(19) United States
(12) Patent Application Publication
(10) Pub. No.: US 2009/0184365 A1
(43) Pub. Date: Jul. 23, 2009

(54) SEMICONDUCTOR MEMORY DEVICE USING SILICON NITRIDE FILM AS CHARGE STORAGE LAYER OF STORAGE TRANSISTOR AND MANUFACTURING METHOD THEREOF

(76) Inventors: Katsuyuki SEKINE, Yokohama-shi (JP); Masaru Kito, Yokohama-shi (JP); Yoshio Ozawa, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/352,673

(22) Filed: Jan. 13, 2009

(30) Foreign Application Priority Data
Jan. 16, 2008 (JP) 2008-007184

(51) Int. Cl. H01L 29/792; H01L 21/336

(52) U.S. Cl. 257/326; 438/287; 257/E29.309; 257/E21.423

(57) ABSTRACT

A semiconductor memory device includes a tunnel insulating film, charge storage layer, block insulating film and control gate electrode stacked and formed on the surface of a semiconductor substrate. The charge storage layer is formed of an insulating film containing nitrogen. A dopant that reduces the trap density of charges moved in and out of an internal portion of the charge storage layer via the tunnel insulating film is doped into a region of the charge storage layer on the interface side with the tunnel insulating film or a dopant is doped into the above region with higher concentration in comparison with that of another region.

### CROSS-REFERENCE TO RELATED APPLICATIONS

This application is based upon and claims the benefit of priority from the prior Japanese Patent Application No. 2008-007184, filed Jan. 16, 2008, the entire contents of which are incorporated herein by reference.

### BACKGROUND OF THE INVENTION

1. Field of the Invention

This invention relates to a semiconductor memory device and a manufacturing method thereof and more particularly to a semiconductor memory device using a silicon nitride film as a charge storage layer of a storage transistor and a manufacturing method thereof.

2. Description of the Related Art

A nonvolatile semiconductor memory device called a MONOS type is known. The MONOS nonvolatile semiconductor memory device is disclosed in Jpn. Pat. Appln. KOKAI Publication No. 2004-363329, for example. The memory device has storage transistors each having source and drain diffusion layers formed on the surface layer portion of a silicon substrate and a gate structure formed by stacking a tunnel insulating film, charge storage layer, block insulating film and control gate electrode. In a general MONOS nonvolatile semiconductor memory device, the tunnel insulating film and block insulating film are formed of insulating films such as a silicon oxide film or Aluminum oxide. Further, the charge storage layer is formed of an insulating film such as a silicon nitride film. The control gate electrode is formed of a conductor such as a metal layer or polysilicon layer.

Recently, the requirement for reducing the power consumption and increasing the operating speed of the MONOS nonvolatile semiconductor memory device with the above structure becomes stronger. In order to meet the requirement, for example, it is necessary to reduce the total film thickness of a stacked insulating film formed by stacking three-layered insulating films of the tunnel insulating film, charge storage layer (silicon nitride film) and block insulating film in order to increase the total electrical capacitance of the stacked insulating film.

However, if the film thickness of the tunnel insulating film is simply reduced while the stacked insulating film is made thin, de-trap of charges tends to occur via the tunnel insulating film from the trap level near the interface between the tunnel insulating film and the charge storage layer when the charge storage layer holds charges. If such a de-trap phenomenon occurs, the charge retention characteristic of the charge storage layer is extremely degraded. Therefore, in the conventional MONOS nonvolatile semiconductor memory device, the tunnel insulating film cannot be made thin and the requirement for reducing the power consumption and increasing the operating speed cannot be satisfied.

### BRIEF SUMMARY OF THE INVENTION

According to one aspect of the present invention, there is provided a semiconductor memory device that includes a tunnel insulating film formed on a main surface of a semiconductor substrate, a charge storage layer formed of an insulating film containing nitrogen on the tunnel insulating film, the charge storage layer being doped with a dopant that reduces trap density of charges existing at near the interface between charge storage layer and tunnel insulating film and detrapped via tunnel insulating film, a block insulating film formed on the charge storage layer, and a control gate electrode formed on the block insulating film.

According to another aspect of the present invention, there is provided a semiconductor memory device that includes a tunnel insulating film formed on a main surface of a semiconductor substrate, a charge storage layer formed of an insulating film containing nitrogen on the tunnel insulating film, the charge storage layer having two regions those dopant concentration are different each other. The dopant concentration of the first region is higher than second region. The dopant can play important role to reduce trap density of charges at interface between charge storage layer and tunnel insulating film, detrapped via tunnel insulating film. A block insulating film formed on the charge storage layer, and a control gate electrode formed on the block insulating film.

Further, according to still another aspect of the present invention, there is provided a manufacturing method of a semiconductor memory device that includes forming a tunnel insulating film on a main surface of a semiconductor substrate, forming a first insulating film doped with a dopant that reduces trap density of charges on the tunnel insulating film, forming a second insulating film that is not doped with the dopant, and acts as a charge storage layer in cooperation with the first insulating film on the first insulating film, forming a block insulating film on the charge storage layer, and forming a control gate electrode on the block insulating film.

### BRIEF DESCRIPTION OF THE SEVERAL VIEWS OF THE DRAWING

FIG. 1 is a cross-sectional view showing the structure of the main portion of a storage transistor in a semiconductor memory device according to a first embodiment of this invention,

FIGS. 2A and 2B are diagrams showing the concentration distributions of a dopant in a charge storage layer of the storage transistor shown in FIG. 1 in a thickness direction,

FIG. 3 is a diagram showing the relation between the trap density and the concentration of a dopant in the charge storage layer of the storage transistor shown in FIG. 1,

FIG. 4 is a diagram showing the charge retention characteristic of the storage transistor shown in FIG. 1 in comparison with the charge retention characteristic of the conventional storage transistor in a graph form,

FIG. 5A is a cross-sectional view showing a first step, for illustrating a manufacturing method of a semiconductor memory device according to a second embodiment of this invention,

FIG. 5B is a cross-sectional view showing a second step, for illustrating the manufacturing method of the semiconductor memory device according to the second embodiment of this invention,

FIG. 6A is a cross-sectional view showing a third step, for illustrating the manufacturing method of the semiconductor memory device according to the second embodiment of this invention,

FIG. 6B is a cross-sectional view showing a fourth step, for illustrating the manufacturing method of the semiconductor memory device according to the second embodiment of this invention,

FIG. 7A is a cross-sectional view showing a fifth step, for illustrating the manufacturing method of the semiconductor memory device according to the second embodiment of this invention,

FIG. 7B is a cross-sectional view showing a sixth step, for illustrating the manufacturing method of the semiconductor memory device according to the second embodiment of this invention, and

FIG. 8 is a cross-sectional view showing a semiconductor memory device according to a third embodiment of this invention and a manufacturing method thereof.

### DETAILED DESCRIPTION OF THE INVENTION

### First Embodiment

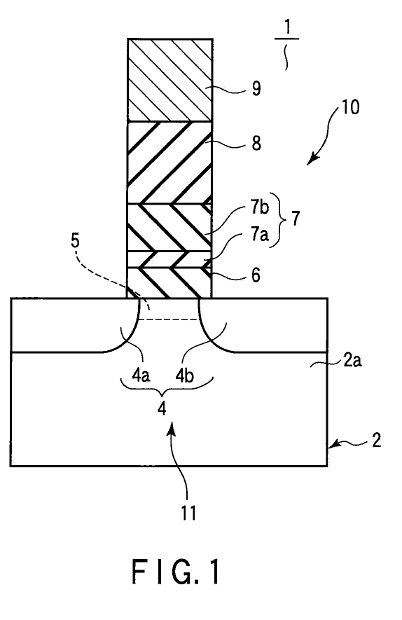

A semiconductor memory device according to a first embodiment of this invention and a manufacturing method thereof are explained with reference to FIGS. 1, 2A, 2B, 3 and 4. The first embodiment is a MONOS nonvolatile semiconductor memory device using a silicon nitride film as a charge storage layer. Specifically, the trap density (trap level) in a portion of the charge storage layer near the interface with the tunnel insulating film is reduced.

FIG. 1 shows the cross-sectional structure of a storage transistor that is the main portion of a MONOS nonvolatile semiconductor memory device 1. As shown in FIG. 1, a formation region 11 for a storage transistor 10 is formed on a surface layer portion 2a of a silicon substrate 2 used as a semiconductor substrate. In practice, a plurality of storage transistor formation regions 11 are formed on the surface layer portion 2a of the silicon substrate 2, but in FIG. 1, one of the formation regions 11 is extracted and shown.

Impurity diffusion layers 4 used as a source diffusion layer 4a and drain diffusion layer 4b are formed on the surface layer portion 2a of the storage transistor formation region 11. A tunnel insulating film 6 is formed at least on the surface of a region 5 that is sandwiched between the source diffusion layer 4a and the drain diffusion layer 4b and acts as a channel region among the surface layer portion 2a of the silicon substrate 2 (storage transistor formation region 11). In this case, not only the surface of the channel region 5 but also the surfaces of the end portions of the source diffusion layer 4a and drain diffusion layer 4b that are connected to the channel region 5 are covered with the tunnel insulating film 6. For example, the tunnel insulating film 6 is formed of a silicon oxide (SiO₂) film.

A charge storage layer 7 is formed on the tunnel insulating film 6. For example, the charge storage layer 7 is formed of an insulating film such as a silicon nitride (SiN) film. Further, a dopant that reduces the trap density of charges that are detrapped at near the interface between the charge storage layer 7 and tunnel insulating film 6 via tunnel insulating film 6 is doped into the internal portion of the charge storage layer 7. In this case, it is assumed that boron (B) that has a p conductivity type and is an element belonging to the III-B group is used as the dopant. Boron tends to combine with nitrogen in the silicon nitride film 7 and stay in the internal portion of the silicon nitride film 7.

Specifically, as shown in FIG. 1, boron is doped into a lower region 7a of the charge storage layer 7 that is a region of the charge storage layer 7 that lies on the interface side with the tunnel insulating film 6. On the other hand, almost no boron is doped in a region 7b that is different from the lower region 7a of the charge storage layer 7 that lies on the interface side with the tunnel insulating film 6. That is, almost no boron is doped in the upper region 7b of the charge storage layer 7 that is a region lying on the interface side with a block insulating film 8 formed on the charge storage layer 7 as will be described later.

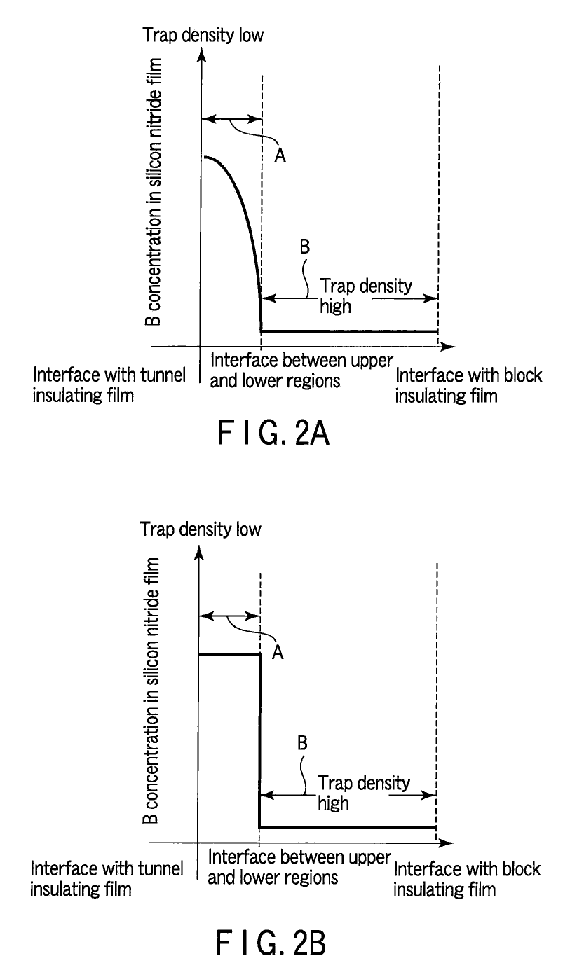

FIGS. 2A and 2B show the concentration distributions (doping profile) of boron in the charge storage layer 7 in the thickness direction. In each of FIGS. 2A and 2B, the range indicated by an arrow A shows the lower region 7a of the charge storage layer 7. Further, the range indicated by an arrow B shows the upper region 7b of the charge storage layer 7. As shown in FIGS. 2A and 2B, the boron concentration in the lower region 7a of the charge storage layer 7 is set higher than the boron concentration in the upper region 7b of the charge storage layer 7. That is, the boron concentration of the charge storage layer 7 is set higher on the tunnel insulating film 6 side and set lower on the block insulating film 8 side. Therefore, as indicated by the arrow A in FIGS. 2A and 2B, the lower region 7a of the charge storage layer 7 acts as a region in which the charge trap density is set lower. On the other hand, as indicated by the arrow B in FIGS. 2A and 2B, the upper region 7b of the charge storage layer 7 acts as a region in which the charge trap density is set higher. The boron concentration distribution in the lower region 7a of the charge storage layer 7, that is, the distribution of the charge trap density can be roughly set to have the following two types of profiles.

As shown in FIG. 2A, one of the profiles is a model in which the boron concentration is distributed to become lower along a curve with a gentle slope in a direction from the interface between the charge storage layer 7 and the tunnel insulating film 6 towards the interface between the lower region 7a and the upper region 7b of the charge storage layer 7. In order to realize the boron concentration distribution having the profile shown in FIG. 2A, for example, a process as will be described below may be performed. First, when the charge storage layer 7 is formed on the tunnel insulating film 6, boron is mixed into a material used to form the charge storage layer 7 in a period from the formation start time of the lower region 7a to the formation termination time in the whole formation process of the charge storage layer 7. Then, the amount of boron mixed into the material used to form the charge storage layer 7 is gradually reduced in a period from the formation start time of the lower region 7a to the formation termination time and the amount of boron mixed into the material used to form the charge storage layer 7 is set to “0” at the formation termination time of the lower region 7a. Thus, the lower region 7a of the charge storage layer 7 containing boron with the concentration distribution along the profile shown in FIG. 2A can be formed.

As shown in FIG. 2B, the other profile is a model in which boron is distributed with substantially the constant concentration in a direction from the interface between the charge storage layer 7 and the tunnel insulating film 6 towards the interface between the lower region 7a and the upper region 7b of the charge storage layer 7. That is, in the model, the edge of the profile in the interface between the lower region 7a and the upper region 7b of the charge storage layer 7 abruptly rises. In this case, the difference between the boron concentration of the lower region 7a and the boron concentration of the upper region 7b in the interface between the lower region 7a and the upper region 7b becomes extremely larger in comparison with a case of the profile shown in FIG. 2A. In order to realize the boron concentration distribution having the profile shown in FIG. 2B, for example, a process as will be described below may be performed. First, like the case of realizing the boron concentration distribution having the profile shown in FIG. 2A, boron is mixed into a material used to form the charge storage layer 7 in a period from the formation start time of the lower region 7a to the formation termination time. However, unlike the case of realizing the boron concentration distribution shown in FIG. 2A, the amount of boron mixed into the material used to form the charge storage layer 7 is set to substantially a constant amount in a period from the formation start time of the lower region 7a to the formation termination time. Then, the amount of boron mixed into the material used to form the charge storage layer 7 is set to “0” at the formation termination time of the lower region 7a. Thus, the lower region 7a of the charge storage layer 7 containing boron with the concentration distribution along the profile shown in FIG. 2B can be formed.

Further, as shown in FIGS. 2A and 2B, in a case wherein one of the above two types of profiles is set as the boron concentration distribution in the lower region 7a of the charge storage layer 7, the boron concentration in the upper region 7b of the charge storage layer 7 is set sufficiently lower than the boron concentration in the lower region 7a of the charge storage layer 7 and is set to substantially 0. In order to realize the boron concentration distribution having the above profile, the upper region 7b of the charge storage layer 7 may be formed by using a material into which boron is not mixed after the lower region 7a of the charge storage layer 7 is formed by use of one of the above described methods. Thus, the upper region 7b of the charge storage layer 7 in which the boron content is substantially “0” can be formed. That is, the lower region 7a of the charge storage layer 7 that is a boron-containing region and the upper region 7b of the charge storage layer 7 that is a non-boron-containing region can be separately formed by selectively determining whether boron is mixed into a material used for formation of the charge storage layer 7. As a result, boron is provided only in part of the whole portion of the charge storage layer 7 that substantially lies near the interface with the tunnel insulating film 6 and the charge storage layer 7 in which the charge trap density in a portion near the interface with the tunnel insulating film 6 is lowered can be formed.

As is clearly understood from the graphs of FIGS. 2A and 2B, the gap of the charge trap density in the interface between the lower region 7a and the upper region 7b is larger in the charge storage layer 7 having the profile shown in FIG. 2B than in the charge storage layer 7 having the profile shown in FIG. 2A. This means that a de-trap phenomenon from the charge trap level via the tunnel insulating film 6 in a portion near the interface with the tunnel insulating film 6 at the charge holding time becomes more difficult to occur in the charge storage layer 7 having the boron concentration distribution shown in FIG. 2B in comparison with the charge storage layer 7 having the boron concentration distribution shown in FIG. 2A. That is, the charge retention characteristic is difficult to be degraded in the charge storage layer 7 having the boron concentration distribution shown in FIG. 2B in comparison with the charge storage layer 7 having the boron concentration distribution shown in FIG. 2A. Therefore, formation of the charge storage layer 7 to contain boron with the concentration distribution along the profile shown in FIG. 2B is more preferable to formation of the charge storage layer 7 to contain boron with the concentration distribution along the profile shown in FIG. 2A.

In the present embodiment, the thickness of the whole portion of the charge storage layer 7 corresponding to a range obtained by adding the ranges indicated by the arrows A and B in FIGS. 2A and 2B is set to approximately 10 nm. In this case, it is preferable to set the thickness of the lower region 7a of the charge storage layer 7 corresponding to the range indicated by the arrow A in FIGS. 2A and 2B to approximately 2 to 3 nm that is approximately 20 to 30% of the whole thickness of the charge storage layer 7. Therefore, it is preferable to set the thickness of the upper region 7b of the charge storage layer 7 corresponding to the range indicated by the arrow B in FIGS. 2A and 2B to approximately 7 to 8 nm that is approximately 70 to 80% of the whole thickness of the charge storage layer 7. With the above settings, the ratio of the charge trap density in the lower region 7a of the charge storage layer 7 to the charge trap density in the upper region 7b of the charge storage layer 7 is preferably set to approximately 1:3 to 1:5. Further, it is preferable to set the thickness obtained by adding together the thickness of the lower region 7a of the charge storage layer 7 and the thickness of the tunnel insulating film 6 to approximately 4 to 6 nm.

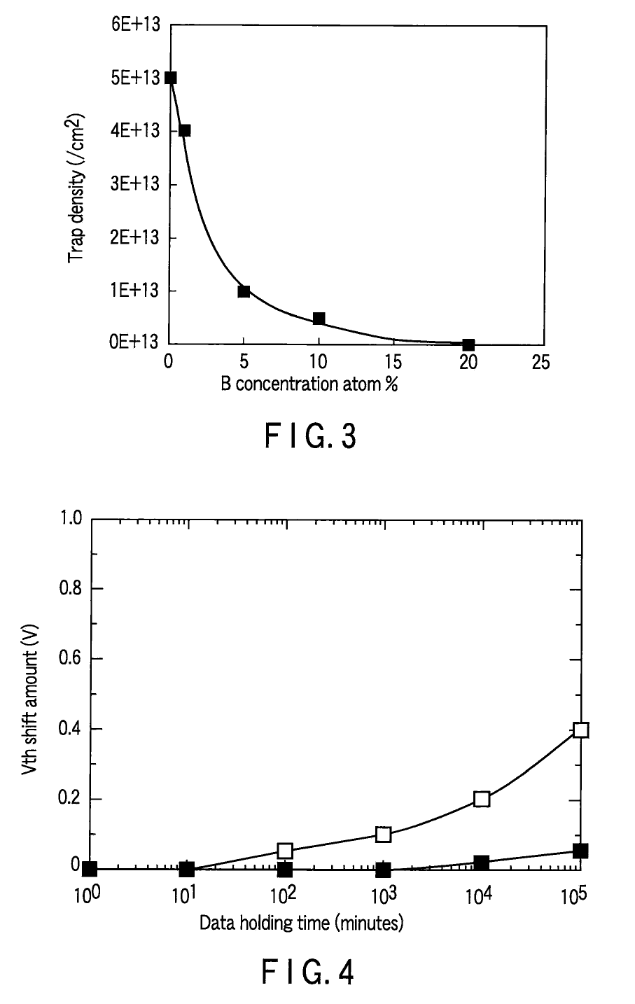

FIG. 3 shows the dependency of the charge trap density on the concentration of a dopant in an SiN film that is the charge storage layer 7 in a graph form. According to the graph shown in FIG. 3, if the boron concentration in the SiN film 7 is 0 atom %, the charge trap density in the SiN film 7 becomes approximately 5×10¹³/cm². If the boron concentration in the SiN film 7 reaches 20 atom %, the charge trap density in the SiN film 7 becomes approximately 0/cm². Thus, the boron concentration in the SiN film 7 and the charge trap density in the SiN film 7 are set in the inversely proportional relation. Therefore, as described before, it is only required to set the concentration of boron contained in the lower region 7a of the charge storage layer 7 to approximately 3 to 5 times the concentration of boron contained in the upper region 7b of the charge storage layer 7 in order to set the charge trap density in the lower region 7a of the charge storage layer 7 to approximately ⅓ to ⅕ the charge trap density in the upper region 7b of the charge storage layer 7.

As shown in FIG. 1, the block insulating film 8 is provided on the upper region 7b of the charge storage layer 7. The block insulating film 8 is formed to prevent charges stored in the charge storage layer 7 from being diffused from the internal portion of the upper region 7b to the exterior. Therefore, the block insulating film 8 is also called a charge block layer. For example, the block insulating film 8 is formed of an alumina (Al₂O₃) film. A control gate electrode 9 is formed on the block insulating film 8. For example, the control gate electrode 9 is formed of a polysilicon layer.

As shown in FIG. 1, the storage transistor 10 that is the main portion of the MONOS nonvolatile semiconductor memory device 1 is configured by the source diffusion layer 4a and drain diffusion layer 4b, the tunnel insulating film (SiO₂ film) 6, the charge storage layer 7 formed of the two-layered structure of the boron-containing SiN film 7a and non-boron-containing SiN film 7b, the block insulating film 8 (Al₂O₃ film) and the control gate electrode (polysilicon layer) 9. The storage transistor 10 with the above structure is provided at least one for each of a plurality of storage transistor formation regions 11. However, in FIG. 1, only one of a plurality of storage transistors 10 is representatively shown.

FIG. 4 shows the charge retention characteristic of the storage transistor 10 provided in the MONOS nonvolatile semiconductor memory device 1 in comparison with the charge retention characteristic of the storage transistor (charge storage layer) provided in the MONOS nonvolatile semiconductor memory device (not shown) according to the prior art in a graph form. In FIG. 4, a graph formed of black-painted squares indicates the charge retention characteristic of the MONOS nonvolatile semiconductor memory device 1 according to the present embodiment. On the other hand, a graph formed of void squares in FIG. 4 indicates the charge retention characteristic of the MONOS nonvolatile semiconductor memory device according to the prior art as a comparison example with respect to the present embodiment.

According to the graphs shown in FIG. 4, it is understood that the shift amount of the threshold value of voltage applied to the charge storage layer 7 is almost not increased even if the data holding time becomes longer in the MONOS nonvolatile semiconductor memory device 1 according to the present embodiment in comparison with a case of the MONOS nonvolatile semiconductor memory device according to the prior art. This means that the charge retention characteristic is greatly improved in the MONOS nonvolatile semiconductor memory device 1 according to the present embodiment in comparison with a case of the MONOS nonvolatile semiconductor memory device according to the prior art. As described before, it is considered that the above effect is based on the fact that the charge trap density in a portion of the charge storage layer 7 lying near the interface with the tunnel insulating film 6, that is, the charge trap level is greatly lowered by doping boron into the region 7a of the charge storage layer 7 lying near the interface with the tunnel insulating film 6. This is because occurrence of a charge de-trap phenomenon from the portion of the charge storage layer 7 lying near the interface with the tunnel insulating film 6 is suppressed when the storage transistor 10 holds charges if the charge trap level in the portion of the charge storage layer 7 lying near the interface with the tunnel insulating film 6 is lowered.

As described above, according to the first embodiment, occurrence of the charge de-trap phenomenon from the portion of the charge storage layer 7 lying near the interface with the tunnel insulating film 6 at the charge holding time of the storage transistor 10 can be suppressed by doping boron into the region 7a of the charge storage layer 7 lying near the interface with the tunnel insulating film 6. Thus, the total electrical capacitance of a stacked insulating film formed of a three-layered insulating film of the tunnel insulating film 6, charge storage layer 7 and block insulating film 8 can be increased without forcedly thinning the tunnel insulating film 6. As a result, the MONOS nonvolatile semiconductor memory device can be formed to have the low power consumption and high operating speed without degrading the charge retention characteristic.

In the invention disclosed in Jpn. Pat. Appln. KOKAI Publication No. 2004-363329 described before, boron is doped into a second charge storage layer of the first and second charge storage layers that lies near the control gate electrode in exactly the opposite case to the present embodiment. Thus, movement of electrons from the control gate electrode to the charge storage layer at the erase time of the storage transistor is suppressed and the effect of increasing the erase speed is attained. On the other hand, in the present embodiment, as described before, boron is doped into the region 7a of the whole portion of the charge storage layer 7 that lies near the interface with the tunnel insulating film 6 lying on the opposite side of the control gate electrode 9. As a result, the charge trap level in a portion of the charge storage layer 7 lying near the interface with the tunnel insulating film 6 is made deep and the effect of suppressing degradation in the charge retention characteristic of the storage transistor 10 caused by extraction of charges via the tunnel insulating film 6 can be attained. Thus, the boron doping position in the charge storage layer and the effect attained are quite different in the present embodiment and the invention disclosed in Jpn. Pat. Appln. KOKAI Publication No. 2004-363329.

### Second Embodiment

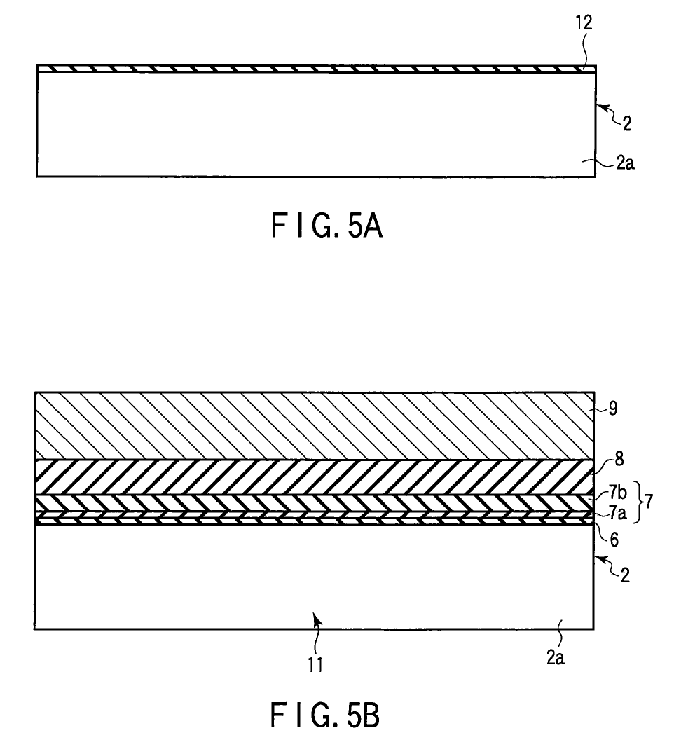

Next, a second embodiment of this invention is explained with reference to FIGS. 5A, 5B, 6A, 6B, 7A and 7B. FIGS. 5A, 5B, 6A, 6B, 7A and 7B are cross-sectional views showing a manufacturing method of a semiconductor memory device according to the present embodiment in a sequential order. Portions that are the same as those of the first embodiment are denoted by the same symbols and the detailed explanation thereof is omitted. The present embodiment specifically shows a manufacturing method of the MONOS nonvolatile semiconductor memory device 1 of the first embodiment.

First, as shown in FIG. 5A, a sacrifice oxide film 12 is formed to cover a surface layer portion 2a of a silicon substrate 2. Then, although not shown in the drawing, an impurity is doped into a storage transistor formation region 11 used as an element formation region in the surface layer portion 2a of the silicon substrate 2 on which the sacrifice oxide film 12 is formed by use of an ion-implantation method.

Subsequently, the silicon substrate 2 into which an impurity is doped is subjected to a heating process (annealing process) to activate the impurity doped into the storage transistor formation region 11. By the process up to the above step, a well region (not shown) is formed in the storage transistor formation region 11. After this, the surface of the silicon substrate 2 on which the well region is formed is cleaned by using dilute hydrofluoric acid.

Next, as shown in FIG. 5B, the silicon substrate 2 whose surface is cleaned is subjected to a heating process at approximately 800 to 900° C. in an oxygen atmosphere. Thus, a silicon oxide (SiO₂) film 6 having a film thickness of approximately 2 to 8 nm is formed on the surface of the silicon substrate 2. The silicon oxide film 6 is used as a tunnel insulating film.

Then, the silicon substrate 2 on which the silicon oxide film 6 is formed is subjected to an ALD process at approximately 450 to 600° C. by using DCS, NH₃ and B₂H₆ as precursors. Thus, a silicon nitride (SiN) film 7a containing boron and having a film thickness of approximately 1 to 3 nm is formed on the surface of the silicon oxide film 6. The boron-containing silicon nitride film 7a acts as a lower region that is a region of the charge storage layer 7 lying on the interface side with the tunnel insulating film 6. When an ALD method used to form the boron-containing silicon nitride film 7a is performed, the ratio of the precursors of DCS, NH₃ and B₂H₆ may be adequately set so that the concentration distribution of boron in the boron-containing silicon nitride film 7a will be set to have the profiles explained with reference to FIGS. 2A and 2B in the first embodiment.

After this, the silicon substrate 2 above which the boron-containing silicon nitride film 7a is formed is subjected to an ALD process at approximately 450 to 600° C. In this case, however, unlike the case wherein the boron-containing silicon nitride film 7a is formed, only DCS and NH₃ are used as precursors and B₂H₆ is not used as a precursor this time. Thus, a silicon nitride (SiN) film 7b containing no boron and having a film thickness of approximately 4 to 10 nm is formed on the surface of the boron-containing silicon nitride film 7a. The non-boron-containing silicon nitride film 7b acts as an upper region that is a region of the charge storage layer 7 lying on the interface side with a block insulating film 8. By the process up to the above step, the charge storage layer 7 of the two-layered structure including the boron-containing silicon nitride film 7a and non-boron-containing silicon nitride film 7b is formed on the silicon oxide film 6 used as the tunnel insulating film.

Subsequently, the silicon substrate 2 above which the charge storage layer 7 is formed is subjected to an ALD process by using oxidizing agents such as TMA and H₂O as precursors. Thus, an alumina (Al₂O₃) film 8 having a film thickness of approximately 10 to 20 nm is formed on the surface of the non-boron-containing silicon nitride film 7b that is the upper region of the charge storage layer 7. The alumina film 8 acts as a block insulating film (charge block layer). Then, the silicon substrate 2 above which the alumina 8 is formed is subjected to an LPCVD method at approximately 550 to 620° C. by using SiH₄ gas. As a result, an amorphous silicon layer 9 is formed on the surface of the alumina film 8. The amorphous silicon layer 9 is modified into a polysilicon layer at the finishing time and used as a control gate electrode.

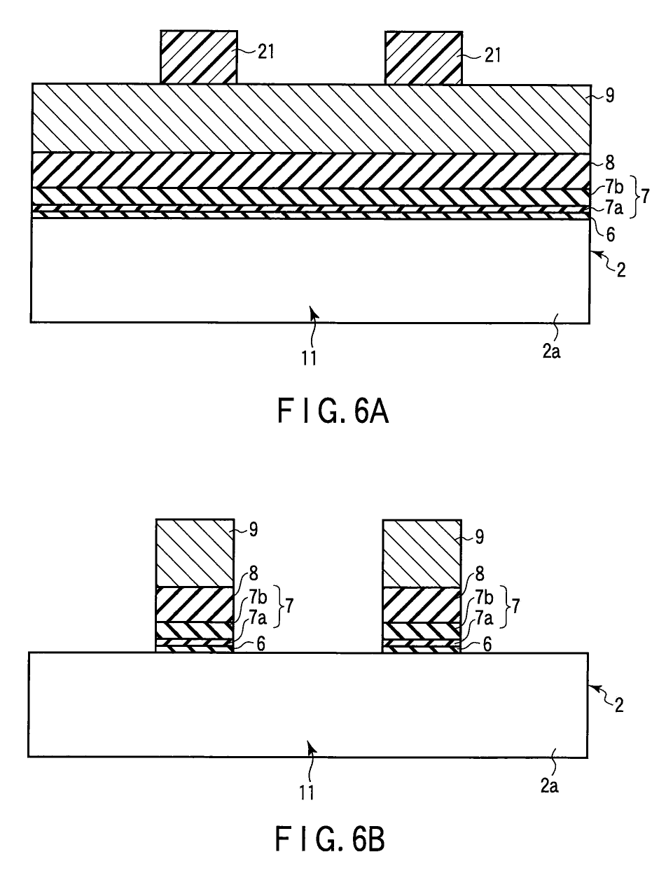

Next, as shown in FIG. 6A, a resist film 21 is formed on the surface of the amorphous silicon layer 9 by use of a coating method. At this time, the resist pattern 21 is patterned into a desired pattern of the control gate electrode 9 by using a normal lithography process.

Then, as shown in FIG. 6B, the amorphous silicon layer 9, alumina film 8, non-boron-containing silicon nitride film 7b, boron-containing silicon nitride film 7a and silicon oxide film 6 are selectively etched with the patterned resist films 21 used as a mask. Thus, the amorphous silicon layer 9, alumina film 8, non-boron-containing silicon nitride film 7b, boron-containing silicon nitride film 7a and silicon oxide film 6 are patterned into a shape corresponding to the desired pattern of the control gate electrode 9. After this, the resist films 21 are removed from the surface of the amorphous silicon layer 9.

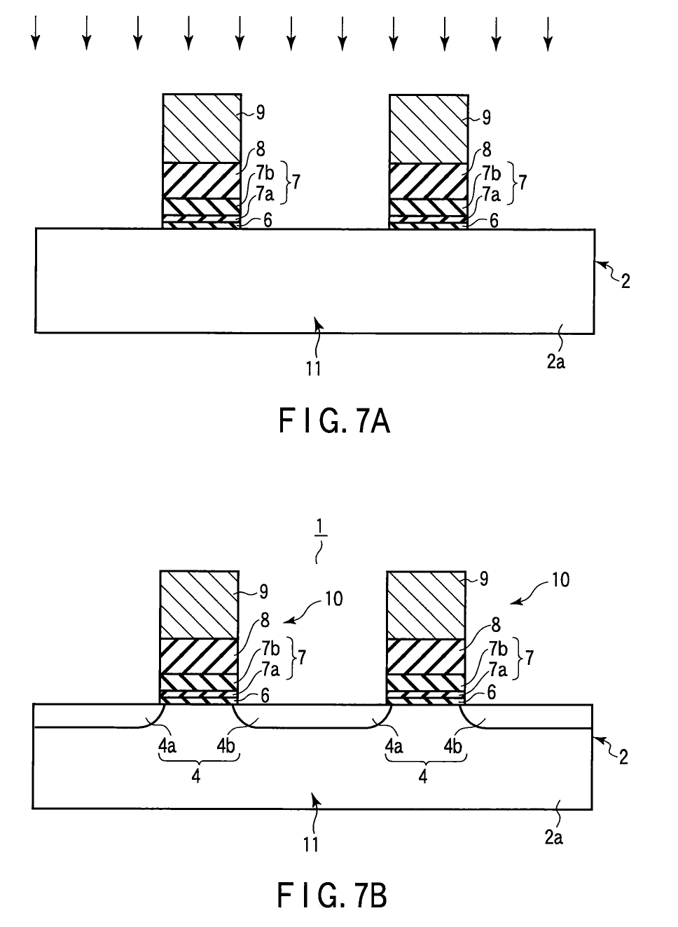

Next, as shown by arrows in FIG. 7A, an impurity is doped into the amorphous silicon layers 9 from which the resist films 21 are removed and impurity diffusion regions 4 used as source diffusion layers 4a and drain diffusion layers 4b by use of an ion-implantation technique. Then, the silicon substrate 2 having the amorphous silicon layers 9 and impurity diffusion regions 4 into which an impurity is doped is subjected to a heating process at approximately 1000° C. for approximately 30 seconds to activate the impurity doped into the amorphous silicon layers 9 and impurity diffusion regions 4. The amorphous silicon layers 9 are modified into polysilicon layers by the heating process.

By the process up to the above step, as shown in FIG. 7B, a plurality of storage transistors 10 that are the main portions of a MONOS nonvolatile semiconductor memory device 1 and respectively formed of the source diffusion layers 4a and drain diffusion layers 4b, tunnel insulating films (SiO₂ films) 6, the charge storage layer 7 each configured by the two-layered structure including the boron-containing silicon nitride film 7a and non-boron-containing silicon nitride film 7b, alumina (Al₂O₃) films 8 and control gate electrodes (polysilicon layers) 9 are formed on the silicon substrate 2. In this case, a case of forming two of the plural storage transistors 10 that are adjacent to each other is shown in FIGS. 5A, 5B, 6A, 6B, 7A and 7B.

As described above, according to the second embodiment, the same effect as that described in the first embodiment can be attained. Further, according to the present embodiment, the MONOS nonvolatile semiconductor memory device 1 that is designed to have the low power consumption and high operating speed without degrading the charge retention characteristic of the charge storage layer 7 can be easily attained.

### Third Embodiment

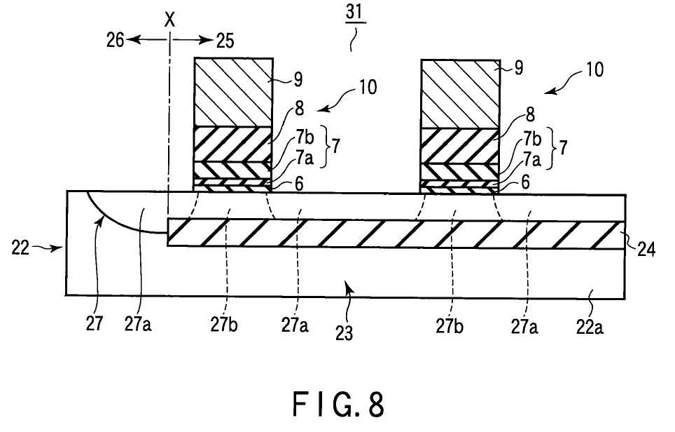

Next, a third embodiment of this invention is explained with reference to FIG. 8. Portions that are the same as those of the first and second embodiments are denoted by the same symbols and the detailed explanation thereof is omitted.

In the MONOS nonvolatile semiconductor memory device 1 according to the first and second embodiments, the source and drain diffusion layers 4a and 4b of the storage transistors 10 that are adjacent to each other are separated from each other. On the other hand, in the present embodiment, a so-called depletion MONOS nonvolatile semiconductor memory device having the structure in which the source and drain diffusion layers of respective storage transistors are integrated and substantially continuously formed and a manufacturing method thereof are explained.

As shown in FIG. 8, in a depletion MONOS nonvolatile semiconductor memory device 31 according to this embodiment, a so-called partial SOI substrate 22 is used as a semiconductor substrate. The partial SOI substrate 22 has an insulating layer 24 that is formed of an insulating coating film of, for example, polysilazane having high fluidity and is partly embedded in a storage transistor formation region 23 of a surface layer portion 22a. A region of the partial SOI substrate 22 in which the embedded insulating layer 24 is provided on the right side of a one-dot-dash line X in FIG. 8 is called an SOI region 25. Further, a region in which the embedded insulating layer 24 is not provided on the left side of the one-dot-dash line X in FIG. 8 is called a non-SOI region 26. Then, a plurality of storage transistors 10 are formed on the surface of the SOI region 25 in the storage transistor formation region 23 of the partial SOI substrate 22 by performing the same steps as those explained with reference to FIGS. 5A, 5B, 6A, 6B, 7A and 7B in the second embodiment. Like the case of FIGS. 5A, 5B, 6A, 6B, 7A and 7B, a case wherein two of the plural storage transistors 10 that are adjacent to each other are formed is shown in FIG. 8.

After this, the surface layer portion 22a of the partial SOI substrate 12 is subjected to a thermal diffusion process. Then, impurities in the source and drain diffusion layers 4a, 4b shown in FIG. 7B are diffused into regions that lie adjacent to the source and drain diffusion layers 4a, 4b and in which no impurity is doped mainly along the surface of the SOI substrate 12. Thus, the source and drain diffusion layers 4a, 4b that lie adjacent to each other are substantially integrated. As a result, as shown in FIG. 8, an impurity diffusion layer 27 is entirely formed above the embedded insulating film 24 to partially cover the end portion of the embedded insulating film 24 that lies on the non-SOI region 26 side. Regions of the impurity diffusion layer 27 that mainly correspond to the source and drain diffusion layers 4a, 4b in FIG. 7B act as regions (high-concentration impurity diffusion regions) 27a in which the impurity concentration is high. On the other hand, regions in which the source and drain diffusion layers 4a, 4b are not mainly formed in FIG. 7B act as regions (low-concentration impurity diffusion regions) 27b in which the impurity concentration is low. Further, the storage transistor 10 used as a memory cell functions as a depletion (D-type) transistor.

By the process up to the above step, a plurality of storage transistors 10 used as memory cells and commonly using the impurity diffusion layer 27 formed of the high-concentration impurity diffusion regions 27a and low-concentration impurity diffusion regions 27b are formed in the SOI region 25. That is, a plurality of main portions of the depletion MONOS nonvolatile semiconductor memory device 31 are formed on the SOI substrate 22.

As described above, according to the third embodiment, even if the partial SOI substrate 22 is used instead of the general silicon substrate 2, the depletion MONOS nonvolatile semiconductor memory device 31 capable of attaining the same effects as those of the first and second embodiments described before can be obtained.

The semiconductor memory device and the manufacturing method thereof according to this invention are not limited to the first to third embodiments. Part of the configuration or the manufacturing process of the above embodiments can be variously modified or various settings can be adequately combined, used and embodied without departing from the technical scope of the invention.

For example, the boron concentration in the upper region 7b of the charge storage layer 7 explained with reference to FIGS. 2A and 2B in the first embodiment is not necessarily set to exactly 0%. For example, in the graph shown in FIG. 2A, a profile may be provided in which the end portion of the charge storage layer 7 that lies on the connection side between the lower region 7a and the upper region 7b slightly protrudes towards the upper region 7b side with respect to the broken lines indicating the interface between the lower region 7a and the upper region 7b. This state may occur with a strong possibility when the upper region 7b is formed on the lower region 7a even in a case wherein boron is contained only in the internal portion of the lower region 7a of the charge storage layer 7 by use of the two formation methods described before or by diffusing boron from the internal portion of the lower region 7a to the internal portion of the upper region 7b after the upper region 7b is formed on the lower region 7a. However, even in such a case, there occurs no problem in practice if the amount of boron contained in the upper region 7b of the charge storage layer 7 is less than a lower limit of detection by use of a general detection device and detection method. That is, if the amount of boron contained in the upper region 7b of the charge storage layer 7 is set to a value so as not to prevent the function of the lower region 7a of the charge storage layer 7 set to make it difficult to cause a de-trap phenomenon of charges via the tunnel insulating film 6 when the charge storage layer 7 holds charges, the boron concentration is not necessarily set to nearly 0%.

Further, a dopant doped into the lower region 7a of the charge storage layer 7 is not limited to boron. As the dopant doped into the lower region 7a of the charge storage layer 7, another element can be used if the element is easily combined with nitrogen in the silicon nitride film like boron. As the above element, for example, aluminum (Al) that is an element belonging to the III-B group like boron and has a p conductivity type may be provided. Alternatively, an element having an n conductivity type that is opposite to the conductivity type of boron can be used. As the above element, for example, phosphorus (P), arsenic (As) or antimony (Sb) belonging to the V-B group may be provided. When the above element is doped into the lower region 7a of the charge storage layer 7, the same effect as that obtained when boron is doped into the lower region 7a of the charge storage layer 7 can be attained. However, oxygen (O) cannot be properly used as a dopant doped into the lower region 7a of the charge storage layer 7 since variation in the dielectric constant of the charge storage layer 7 into which oxygen is doped becomes large and there is a strong possibility that the original charge storage function of the charge storage layer 7 may be degraded. That is, in order not to prevent the original charge storage function of the charge storage layer 7, it is preferable to use a substance that prevents the dielectric constant of the charge storage layer 7 into which the substance is doped from being largely varied as a dopant doped into the lower region 7a of the charge storage layer 7.

In the first and second embodiments, the charge storage layer 7 is formed of the stacked film including the silicon nitride film 7a containing boron and the silicon nitride film 7b containing no boron. However, this invention is not limited to this case. It is possible to form the whole portion of the charge storage layer 7 by using a single-layered silicon nitride film, for example, and dope boron into the whole portion of the single-layered silicon nitride film 7 so that the boron concentration in the single-layered silicon nitride film 7 will become lower in a direction from the interface side thereof with the tunnel insulating film 6 towards the interface side thereof with the block insulating film 8. Even when the charge storage layer 7 is formed of the above material, the same effect as that obtained when the charge storage layer 7 is formed of the stacked film including the boron-containing silicon nitride film 7a and non-boron-containing silicon nitride film 7b can be attained.

Further, a method for forming the charge storage layer 7 formed of the stacked film including the boron-containing silicon nitride film 7a and non-boron-containing silicon nitride film 7b is not limited to the method explained in the second embodiment. For example, first, a silicon nitride film containing no boron is formed on the tunnel insulating film 6 by use of a general ALD method or LPCVD method. Then, boron is doped into the silicon nitride film containing no boron by an ion-implantation method or a vapor-phase diffusion method using B₂H₆. After this, a silicon nitride film 7b containing no boron is formed on the silicon nitride film 7a having boron doped therein by using the general ALD method or LPCVD method. By the above method, like the first and second embodiments, the charge storage layer that is formed of the stacked film including the boron-containing silicon nitride film 7a and non-boron-containing silicon nitride film 7b can be formed.

Further, in the first and second embodiments, the tunnel insulating film 6 is formed of a single-layered silicon oxide film but is not limited to this silicon oxide film. For example, the tunnel insulating film 6 may be formed of a single-layered film of a silicon nitride film or a silicon oxy-nitride (SiON) film. Alternatively, the tunnel insulating film 6 can be formed of a stacked film obtained by combining at least two types of insulating films selected from a silicon oxide film, silicon oxy-nitride film and silicon nitride film, for example. Even if the tunnel insulating film 6 is formed with the above structure, the same effect as that obtained when the tunnel insulating film 6 is formed of the single-layered silicon oxide film can be attained.

When the tunnel insulating film 6 is formed of a single-layered silicon oxy-nitride film, a silicon oxide film may be first formed by use of the method explained in the second embodiment and then the silicon oxide film may be subjected to a heating process at approximately 800 to 1000° C. in an atmosphere of gas such as ammonia (NH₃), dinitrogen monoxide (N₂O) or nitrogen monoxide (NO) containing nitrogen. Thus, nitrogen can be contained in the silicon oxide film to modify the silicon oxide film into a silicon oxy-nitrogen film. Alternatively, a silicon oxide film can be modified into a silicon oxy-nitrogen film by first forming the silicon oxide film by use of the method explained in the second embodiment and then causing the silicon oxide film to contain nitrogen by a plasma nitriding method.

Further, in the first and second embodiments, the block insulating film 8 is formed of a single-layered alumina film but is not limited to this film. The block insulating film 8 may be formed of a single-layered film of a silicon oxide film, silicon oxy-nitride film or lanthanum aluminate film, for example.

Alternatively, the block insulating film 8 can be formed of a stacked film obtained by combining at least two types of insulating films selected from a silicon oxide film, silicon oxy-nitride film, lanthanum aluminate film and alumina film, for example. Further, another insulating film formed of a single-layered film or stacked film may be disposed between the block insulating film 8 and the charge storage layer 7. Even if the block insulating film 8 is formed with the above structure, the same effect as that obtained when the block insulating film 8 is formed of the single-layered alumina film can be attained. Also, in the second embodiment, the block insulating film 8 is formed by use of an ALD method, but the block insulating film 8 can be formed by use of a sputtering method.

As described above, according to one aspect of this invention, a semiconductor memory device in which the power consumption can be reduced and the operating speed can be increased without degrading the charge retention characteristic and a manufacturing method thereof can be provided.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a tunnel insulating film formed on a main surface of a semiconductor substrate,
a charge storage layer formed of an insulating film containing nitrogen on the tunnel insulating film, the charge storage layer being doped with a dopant that reduces trap density of charges moved in and out of an internal portion of a region lying on an interface side with the tunnel insulating film via the tunnel insulating film, (p.3 [symbol] )
a block insulating film formed on the charge storage layer, and
a control gate electrode formed on the block insulating film.

2. The semiconductor memory device according to claim 1, wherein thickness of the region on the interface side of the charge storage layer with the tunnel insulating film is not larger than 30% of thickness of a whole portion of the charge storage layer.

3. The semiconductor memory device according to claim 1, further comprising source and drain diffusion layers separately formed in surface layer portions of the semiconductor substrate corresponding to gate structure formed by stacking the tunnel insulating film, charge storage layer, block insulating film and control gate electrode.

4. The semiconductor memory device according to claim 1, wherein the dopant includes one of an element belonging to a III-B group and an element belonging to a V-B group.

5. The semiconductor memory device according to claim 4, wherein the element belonging to the III-B group includes boron and aluminum and the element belonging to the V-B group includes phosphorus, arsenic and antimony.

6. The semiconductor memory device according to claim 1, wherein the charge storage layer is a silicon nitride film formed by causing boron to be doped in a region lying near the interface with the tunnel insulating film.

7. The semiconductor memory device according to claim 1, wherein the charge storage layer is a stacked film of a boron-containing silicon nitride film and non-boron-containing silicon nitride film.

8. The semiconductor memory device according to claim 1, wherein the semiconductor substrate is a partial SOI substrate.

9. A semiconductor memory device comprising:
a tunnel insulating film formed on a main surface of a semiconductor substrate,
a charge storage layer formed of an insulating film containing nitrogen on the tunnel insulating film, the charge storage layer having a first region in which a dopant that reduces trap density of charges moved in and out of an internal portion thereof on an interface side with the tunnel insulating film via the tunnel insulating film is doped with first concentration and a second region formed on the first region and in which the dopant is doped with second concentration lower than the first concentration,
a block insulating film formed on the charge storage layer, and
a control gate electrode formed on the block insulating film.

10. The semiconductor memory device according to claim 9, wherein thickness of the region on the interface side of the charge storage layer with the tunnel insulating film is not larger than 30% of thickness of a whole portion of the charge storage layer.

11. The semiconductor memory device according to claim 9, further comprising source and drain diffusion layers separately formed in surface layer portions of the semiconductor substrate corresponding to gate structure formed by stacking the tunnel insulating film, charge storage layer, block insulating film and control gate electrode.

12. The semiconductor memory device according to claim 9, wherein the dopant includes one of an element belonging to a III-B group and an element belonging to a V-B group.

13. The semiconductor memory device according to claim 12, wherein the element belonging to the III-B group includes boron and aluminum and the element belonging to the V-B group includes phosphorus, arsenic and antimony.

14. The semiconductor memory device according to claim 9, wherein the charge storage layer is a silicon nitride film formed by causing boron to be doped in the first region lying near the interface with the tunnel insulating film.

15. A manufacturing method of a semiconductor memory device comprising:
forming a tunnel insulating film on a main surface of a semiconductor substrate,
forming a first insulating film doped with a dopant that reduces trap density of charges and containing nitrogen on the tunnel insulating film,
forming a second insulating film that is not doped with the dopant, contains nitrogen and acts as a charge storage layer in cooperation with the first insulating film on the first insulating film,
forming a block insulating film on the charge storage layer, and
forming a control gate electrode on the block insulating film.

16. The manufacturing method of the semiconductor memory device according to claim 15, wherein forming the first insulating film includes gradually reducing an amount of the dopant from formation start time to formation termination time and setting the amount to zero at the formation termination time.

17. The manufacturing method of the semiconductor memory device according to claim 16, wherein forming the second insulating film includes forming an insulating film into which the dopant is not substantially mixed on the first insulating film.

18. The manufacturing method of the semiconductor memory device according to claim 15, wherein forming the first insulating film includes doping the dopant of substantially a constant amount from the formation start time to the formation termination time.

19. The manufacturing method of the semiconductor memory device according to claim 18, wherein forming the second insulating film includes forming an insulating film into which the dopant is not substantially mixed on the first insulating film.

20. The manufacturing method of the semiconductor memory device according to claim 15, further comprising patterning the tunnel insulating film, charge storage layer, block insulating film and control gate electrode to form stacked gate structure, and doping an impurity into the semiconductor substrate to separately form source and drain diffusion layers with the stacked gate structure used as a mask.
